(19) United States
(12) Patent Application Publication
(10) Pub. No.: US 2009/0224343 A1
(43) Pub. Date: Sep. 10, 2009

(54) METHODS OF FORMING IMAGER DEVICES, IMAGER DEVICES CONFIGURED FOR BACK SIDE ILLUMINATION, AND SYSTEMS INCLUDING THE SAME

(75) Inventor: Salman Akram, Boise, ID (US)

Correspondence Address: Treyz Law Group, 870 Market Street, Suite 984, San Francisco, CA, 94102, US

(73) Assignee: MICRON TECHNOLOGY, INC., Boise, ID (US)

(21) Appl. No.: 12/043,651

(22) Filed: Mar. 6, 2008

(51) Int. Cl. H01L 31/0232; H01L 31/18

(52) U.S. Cl. 257/432; 438/69; 257/E31.127

(57) ABSTRACT

Imager devices configured for back side illumination include a structural support member surrounding a sensor array. A conductive element for communicating electrically with the sensor array may be provided on a front side of the sensor array. In some embodiments, a plurality of conductive elements may be provided on the front side of the sensor array, and each conductive element may be vertically aligned with the structural support member. Imaging systems include such imager devices. Methods of forming an imager device are also disclosed.

### FIELD OF THE INVENTION

Embodiments of the present invention relate to devices capable of capturing or acquiring an electronic representation of an image, which are often referred to as “imager” devices, to methods of forming such imager devices, and to systems including such imager devices.

### BACKGROUND OF THE INVENTION

Microelectronic imagers are devices used to capture images in a wide variety of electronic devices and systems including, for example, digital cameras, cellular telephones, computers, personal digital assistants (PDAs), etc. The number of microelectronic imagers produced each year has been steadily increasing as they become smaller and capable of capturing images of improved resolution.

Microelectronic imagers typically include a sensor array that includes a plurality of photosensitive devices, each of which is configured to generate an electrical signal in response to electromagnetic radiation (e.g., visible light) impinging thereon. The photosensitive devices of an imager may include, for example, photodiodes, phototransistors, photoconductors, or photogates. Furthermore, there are different types or configurations of such photosensitive devices including, for example, charged coupled devices (CCD), complementary metal-oxide semiconductor (CMOS) devices, or other solid-state devices. The photosensitive devices are arranged in an array in a focal plane. Each photosensitive device is sensitive to radiation in such a way that it can create an electrical charge that is proportional to the intensity of radiation striking the photosensitive device. The array of photosensitive devices is used to define an array of pixels, each of which is configured to detect the intensity of the radiation impinging thereon. A single pixel may include a single photosensitive device, or a pixel may be defined as a local group of nearest-neighbor photosensitive devices in the array of photosensitive devices. In some imagers, each pixel may be configured to detect radiation impinging thereon over a broad frequency range. Such pixels may be used to capture gray scale images. In additional imagers, each pixel may be configured for detecting a specific wavelength or range of wavelengths of radiation (i.e., a specific color of light) such as, for example, radiation in the visible red, green, or blue regions of the electromagnetic spectrum. In such embodiments, a full color image may be detected and captured with the proper combination of color sensing pixels.

Some CMOS imagers include an array of pixels in which each pixel includes a pixel circuit having three transistors (often referred to as a “3T” pixel circuit). Such 3T pixel circuits may include a photosensitive device for supplying charge (generated in response to radiation impinging thereon) to a diffusion region, a reset transistor for resetting the potential of the diffusion region, a source follower transistor having a gate connected to the diffusion region for producing an output signal, and a row select transistor for selectively connecting the source follower transistor to a column line of a sensor array. Other CMOS imagers include an array of pixels in which each pixel includes a pixel circuit having four transistors (often referred to as a “4T” pixel circuit). A 4T pixel circuit is similar to a 3T pixel circuit, hut also includes a charge transfer transistor to selectively control flow of current from the photosensitive device to a sensing node such as a floating diffusion region.

In addition to the sensor array (which includes the photosensitive devices defining the pixels and the pixel circuits), microelectronic imagers may further include other components or subsystems such as, for example, a controller, a row decoder, a column decoder, etc. Each of these components or subsystems, together with the sensor array, may be integrally formed on a substrate to form the microelectronic imager device. The substrate may include, for example, a full or partial wafer comprising a semiconductor material such as silicon, germanium, gallium arsenide, indium phosphide, or any other III-V type semiconductor material.

### BRIEF DESCRIPTION OF THE SEVERAL VIEWS OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings, in which:

FIG. 1 is a simplified block diagram of an embodiment of an imager device of the present invention;

FIG. 2 is a top plan view illustrating an embodiment of a physical layout of a sensor array and peripheral circuitry for the embodiment of the imager device of FIG. 1;

FIG. 3A is a perspective view illustrating one embodiment of the imager device of FIG. 1 that includes a CMOS sensor array;

FIG. 3B is a perspective view of the embodiment of the imager device shown in FIG. 3A illustrating an opposite side thereof;

FIG. 4A is a top plan view illustrating one embodiment of a physical layout for each of the pixels of the imager device shown in FIGS. 3A-3B;

FIG. 4B is a circuit diagram of the pixel shown in FIG. 4A;

FIG. 4C is a cross-sectional view of the pixel shown in FIG. 4A, taken along section line A-A therein;

FIGS. 5A-5F illustrate one embodiment of a method that may be used to fabricate an imager such as that shown in FIGS. 3A-3B;

FIG. 6 is a cross-sectional view of the embodiment of the imager device shown in FIGS. 3A-3B illustrating an additional substrate that is attached to a front side of the imager device and that may include a redistribution layer;

FIG. 7 is a cross-sectional view of the embodiment of the imager device shown in FIGS. 3A-3B illustrating a relatively larger lens attached thereto and configured to focus radiation onto the sensor array of the imager device; and

FIG. 8 is a simplified block diagram illustrating an embodiment of an imaging system that includes the imager device shown in FIGS. 3A-3B.

### DETAILED DESCRIPTION OF THE INVENTION

In the following detailed description, reference is made to the accompanying drawings which form a part hereof, and in which is shown by way of illustration specific embodiments in which the invention may be practiced. These embodiments are described in sufficient detail to enable those skilled in the art to practice the inventions and it is to be understood that other embodiments may be utilized, and that structural, logical, and electrical changes may be made without departing from the spirit and scope of the present invention.

In some embodiments of the present invention, which are described in further detail below, an imager device configured for back side illumination includes a sensor array and a structural support member at least partially surrounding the sensor array. In some embodiments, the structural support member may be provided on the back side of the sensor array. Furthermore, at least one conductive element for enabling communication by external circuitry with the sensor array may be provided on the front side thereof. In some embodiments, a plurality of such conductive elements may be provided on the front side of the imager device, and each of the conductive elements may be vertically aligned with the structural support member.

In other embodiments of the present invention, imaging systems for capturing an electrical representation of an image include at least one electronic signal processor, at least one memory storage device, and at least one imager device configured to communicate electrically with the at least one memory storage device and the at least one electronic signal processor. The at least one imager device is configured for back side illumination and includes a structural support member at least partially surrounding a sensor array. In some embodiments, the structural support member may be provided on the back side of the sensor array. Furthermore, at least one conductive element for communicating electrically with the sensor array may be provided on the front side thereof. In some embodiments, a plurality of such conductive elements may be provided on the front side of the imager device, and each of the conductive elements may be vertically aligned with the structural support member.

In yet additional embodiments of the present invention, methods of forming imager devices include forming a sensor array on a front side of a layer of material. A structural support member is provided at least partially around the sensor array. At least one conductive element for communicating electrically with the sensor array may be provided on the front side of the layer of material, and the imager device is configured for back side illumination. In some embodiments, the structural support member may be provided on the back side of the layer of material. Furthermore, in some embodiments, the methods may be carried out at the so-called “wafer level” so as to simultaneously form a plurality of imager devices side-by-side on a single substrate.

In this description, circuits and functions may be shown in block diagram form in order not to obscure the present invention in unnecessary detail. Conversely, specific circuit implementations shown and described are only non-limiting examples, and should not be construed as the only way to implement the present invention unless specified otherwise herein. Additionally, block definitions and partitioning of logic between various blocks is only a non-limiting example of a specific implementation. It will be readily apparent to one of ordinary skill in the art that the present invention may be, practiced by numerous other partitioning solutions. For the most part, details concerning timing considerations and the like have been omitted where such details are not necessary to obtain a complete understanding of the present invention and are within the abilities of persons of ordinary skill in the relevant art.

The terms “substrate” and “wafer,” as used herein, mean any structure that includes a layer of semiconductor type material including, for example, silicon, germanium, gallium arsenide, indium phosphide, and other III-V type semiconductor materials. Substrates and wafers include, for example, silicon-on-insulator (SOI) type substrates, silicon-on-sapphire (SOS) type substrates, and epitaxial layers of silicon supported by a layer of base material. Semiconductor type materials may be doped or undoped. Furthermore, when reference is made to a “wafer” or “substrate” in the following description, previous process steps may have been utilized to at least partially form elements or components of a circuit or device in or over a surface of the wafer or substrate.

The term “pixel,” as used herein, refers to a unit cell of a sensor array that includes at least one photosensitive device and one or more transistors for converting electromagnetic radiation impinging on the photosensitive device to an electrical signal.

As used herein, the term “front side” of a sensor array means the side of a substrate or layer of material on or in which the sensor array is formed. Similarly, the term “back side” of a sensor array means the side of a substrate or layer of material opposite the side of the substrate or layer of material on or in which the sensor array is formed.

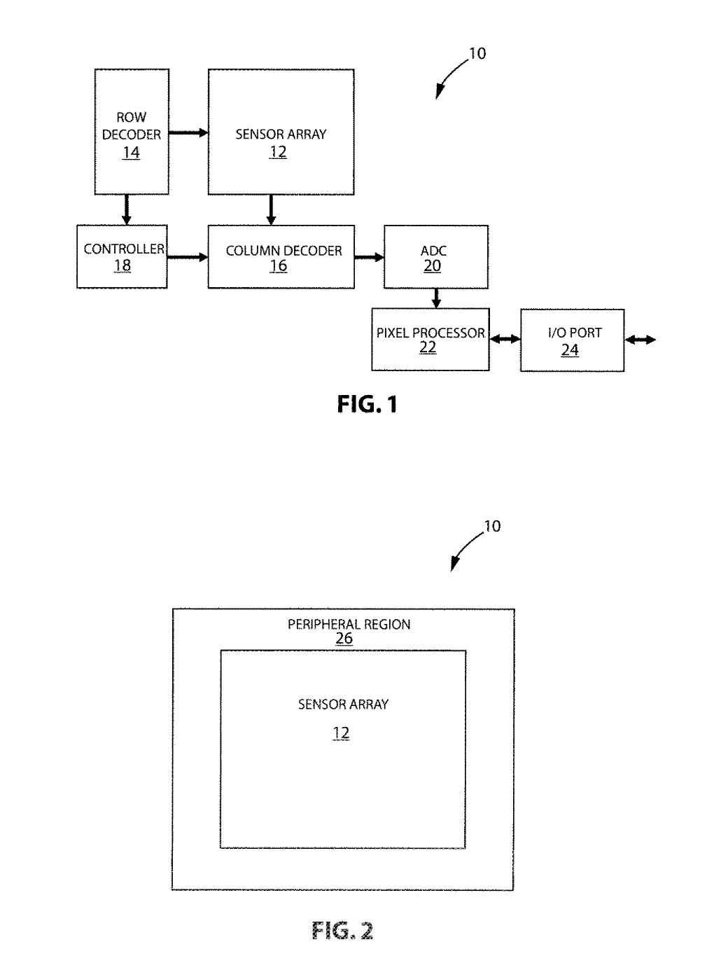

FIG. 1 is a simplified block diagram of an embodiment of an imager device 10 of the present invention. As shown in FIG. 1, the imager device 10 may include a sensor array 12, a row decoder 14, a column decoder 16, and a controller 18. The sensor array 12 (which includes an array of pixels and may also be referred to as a pixel array) includes a plurality of pixels each comprising at least one photosensitive device such as, for example, a photodiode, a phototransistor, a photoconductor, or a photogate. Each pixel may be configured to generate an electrical charge, the magnitude of which may be proportional to the intensity of radiation impinging on the pixel. Each pixel in the sensor array is configured to detect the intensity of radiation impinging on the location of the sensor away in which that respective pixel is located, and to generate an output signal. The overall image captured by the sensor array 12 comprises or is formed from the output signals acquired from each of the pixels in the sensor array 12.

In some embodiments of the imager device 10, each pixel may be configured to detect radiation impinging thereon over a broad frequency range, and the imager device 10 may be configured to capture gray scale images. In additional embodiments, each pixel of the sensor array 12 may be configured for detecting a specific wavelength or range of wavelengths of radiation (i.e., a specific color of light) such as, for example, radiation in the visible red, green, or blue regions of the electromagnetic spectrum. In such embodiments, the imager device 10 may be configured to capture a full color image.

The pixels of the sensor array 12 may be arranged in individually addressable rows and columns such that the row decoder 14 can address each row of the sensor array 12 and the column decoder 16 can address each column of the sensor array 12. While not illustrated with connections in the block diagram shown in FIG. 1, the controller 18 may control functions of many or all of the other components or subsystems within the imager device 10. For example, the controller 18 may control the exposure time of the sensor array 12 when capturing an image and the sequencing of the row decoder 14 and column decoder 16 to read out the analog values of each pixel within the sensor array 12.

By way of example and not limitation, the row decoder 14 may select a specific row and the column decoder 16 may receive an output signal from every pixel in the selected row in parallel. The column decoder 16 then may sequence through each pixel within the selected row to determine the charge on each pixel. As the pixels are each individually addressed, the resulting analog signal from each pixel may be sequentially directed from the column decoder 16 to an analog to digital converter (ADC) 20. The analog to digital converter 20 may be used to convert the analog signal for each pixel to a digital signal representing the intensity of the radiation at each respective pixel.

The digital output signal for each pixel may be directed through a pixel processor 22. The pixel processor 22 may perform a number of functions on the digital output signal being processed. By way of example and not limitation, if the digital output signal for a particular pixel is identified as exhibiting unexpected values (which may indicate that the particular pixel includes an anomaly or defect), the value of the digital output signal for that respective pixel may be replaced with a new value. For example, the value may be replaced by the value of the digital output signal exhibited by a neighboring pixel or an average value from a number of neighboring pixels. In addition, other signal processing functions, such as, for example, filtering and compression may be performed by the pixel processor 22.

After processing, the digital output signal for each pixel may be transferred to an input/output (I/O) port 24 for transmission out of the imager device 10. The I/O port 24 may include a data memory or storage medium to store values from a number of pixels such that pixel values may be transferred out of the imager device 10 in a parallel or serial manner.

FIG. 2 is a top plan view illustrating one embodiment of a physical layout that may be exhibited by the imager device 10. As shown in FIG. 2, in some embodiments, the sensor array 12 of the imager device 10 may be generally centrally located and entirely surrounded by a peripheral region 26. In some embodiments, one or more of the row decoder 14, column decoder 16, controller 18, analog to digital converter 20, pixel processor 22, and I/O port 24 (FIG. 1) may be located in the peripheral region 26 of the imager device 10. In additional embodiments, the sensor array 12 of the imager device 10 may not be centrally located and the peripheral region 26 may only partially surround the sensor array 12. For example, the peripheral region 26 may be disposed on only one, two, or three sides of the sensor array 12.

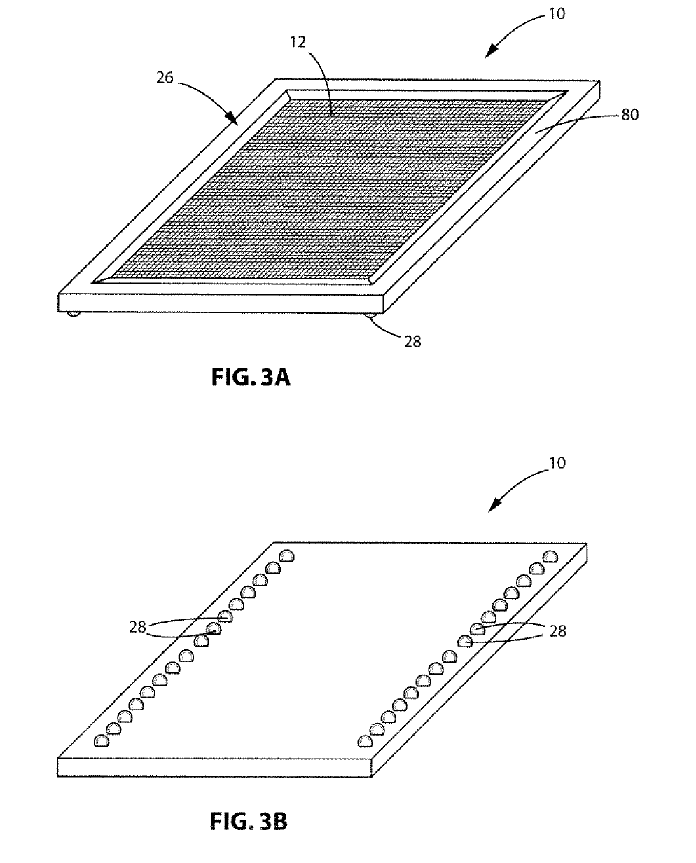

FIG. 3A is a perspective view of an upper surface of one particular embodiment of the imager device 10. As previously mentioned and shown in FIG. 3A, the sensor array 12 may be substantially centrally located, and the peripheral region 26 may entirely surround the sensor array 12. FIG. 3B is a perspective view of an opposite side of the imager device 10 shown in FIG. 3A. As shown in FIG. 3B, the imager device 10 may include a plurality of conductive elements 28 for establishing electrical communication between the imager device 10 and a higher level substrate or device, such as, for example, a circuit board of an electronic device (e.g., a digital camera, a cellular telephone, a computer, a personal digital assistant (PDA), etc.). In some embodiments, each of the conductive elements 28 may be disposed in the peripheral region 26 of the imager device 10 as shown in FIG. 3B and discussed in further detail below.

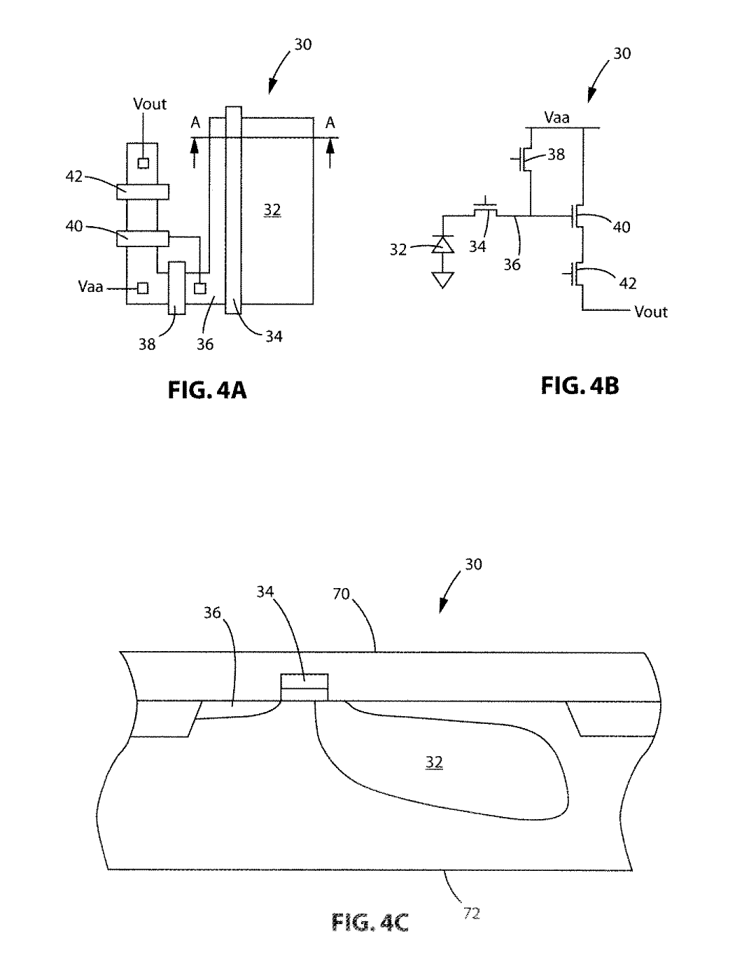

A brief discussion of one embodiment of a pixel 30 (a plurality of which may be included in the sensor array 12) is set forth below with reference to FIGS. 4A-4C merely to provide a non-limiting example of the various types of photosensitive devices that may be present in the sensor array 12.

FIG. 4A is a top plan view illustrating one embodiment of a layout of the pixel 30 in accordance with the present invention. FIG. 4B is a circuit diagram of the pixel 30 of FIG. 4A. Finally, FIG. 4C is a cross-sectional view of the pixel 30 shown in FIG. 4A taken along section line A-A shown therein. The pixel 30 includes a photodiode 32, a charge transfer transistor 34, a floating diffusion region 36, a reset transistor 38, a source follower transistor 40, and a row select transistor 42. The photodiode 32 and the four transistors together provide a four transistor (4T) pixel circuit. Those of ordinary skill in the art will recognize that the sensor array of imager devices according to embodiments of the present invention, such as the sensor array 12 of the imager device 10, may include any of a wide variety of embodiments of pixels and pixel circuits other than the one illustrated in FIGS. 4A-4C, and that the pixels thereof (e.g., the pixel 30) may include components or devices other than those shown in FIGS. 4A-4C such as, for example, resistors, capacitors, photoconductors, phototransistors and photogates. For example, in some embodiments, each pixel 30 may comprise a three transistor (3T) pixel circuit.

In operation, the reset transistor 38 may be used to place, or set, the potential of the floating diffusion region 36 to a known potential, such as substantially near the potential of the voltage source Vaa. Either before or after setting the floating diffusion region 36 to the known potential, the photodiode 32 may be exposed to radiation. As the radiation impinges on the photodiode 32, electrical charge (e.g., electrons) may be generated in the photodiode 32. The charge transfer transistor 34 may be configured and used to selectively transfer the charge generated by the photodiode 32 onto the floating diffusion region 36. The floating diffusion region 36 may be electrically coupled to the gate of the source follower transistor 40 such that the charge on the floating diffusion region 36 regulates the electrical signal at the drain of the source follower transistor 40. In this configuration, the voltage of the electrical signal at the drain of the source follower transistor 4 may be proportional to the charge on the floating diffusion region 36. The row select transistor 42 may be configured and used to selectively allow the signal at the drain of the source follower transistor 40 to be presented on the output signal Vout of the pixel 30.

As also shown in FIG. 4C, each pixel 30 also may include isolation regions 44. For example, the isolation region 4 shown on the right side of FIG. 4C may be used to isolate the photodiode region 32 from any other device in the sensor array 12 (FIG. 3A). Similarly, the isolation region 4 on the left side of FIG. 4C may be used to isolate the floating diffusion region 36 from other devices in the sensor array 12 (FIG. 3A).

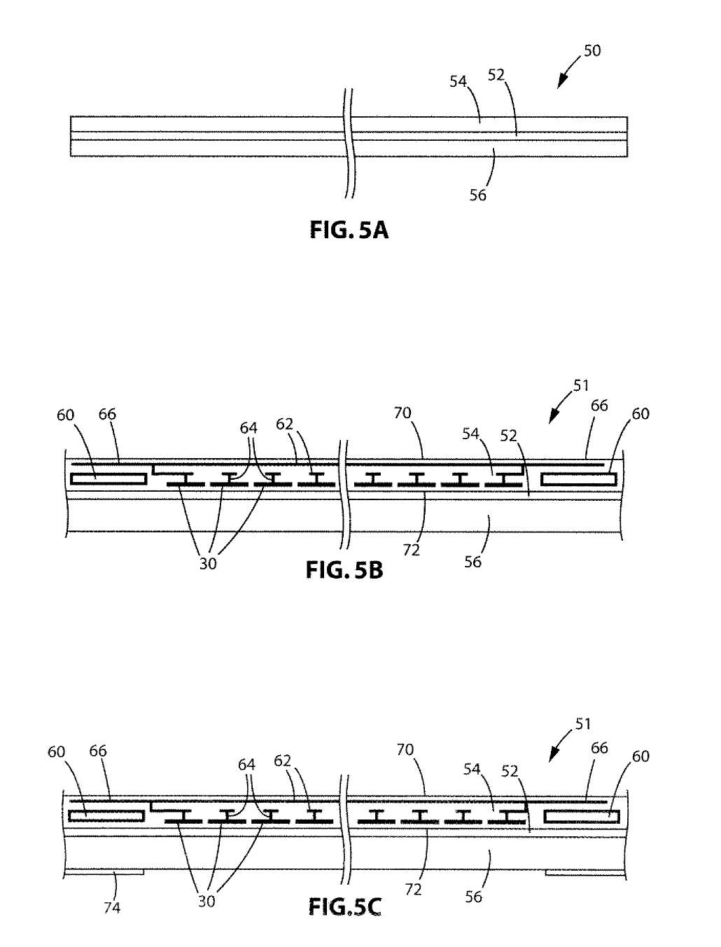

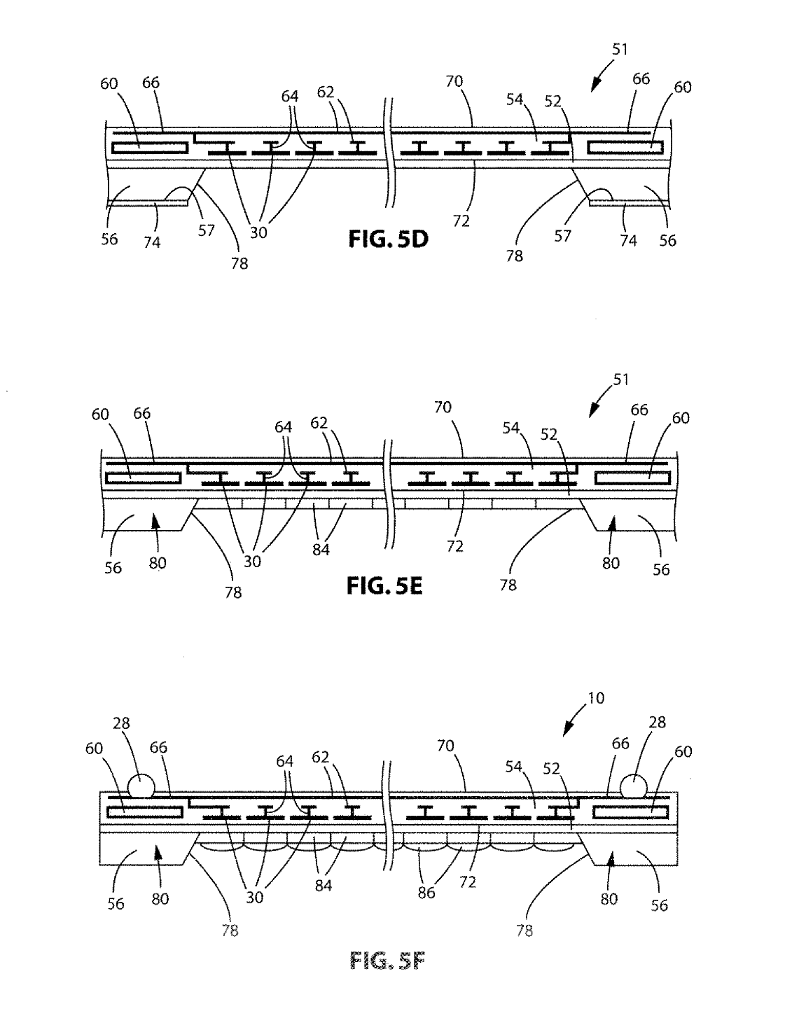

Imager devices according to embodiments of the present invention, such as the imager device 10 shown in FIGS. 3A-3B, may be configured for illumination from what is conventionally referred to as the “back side” of the sensor array 12 and the pixels 30 herein. Specifically, imager device 10 may have the sensor array thereof formed in a layer of semiconductive material which is sufficiently thin, and sufficiently light-transmissive, to enable light penetrating the back side of the sensor array 12 to stimulate pixels 30 thereof. An example of a method that may be used to form the imager device 10 is described below with reference to FIGS. 5A-5G to more fully illustrate how the imager device 10 is configured for illumination from the back side of the sensor array 12.

Referring to FIG. 5A, a substrate 50 may be provided that includes an etch stop layer 52. A first silicon layer 54 may be provided on a first side of the etch stop layer 52, and a second silicon layer 56 may be provided on a second, opposing side of the etch stop layer 52. Of course, one of ordinary skill in the art will recognize that the first and second silicon layers 54, 56 may be replaced with layers of other types of semiconductor materials including, for example, germanium, gallium arsenide, indium phosphide, or other III-V type semiconductor materials in additional embodiments of the present invention.

In some embodiments, the first silicon layer 54 may comprise a so-called “device wafer,” which is configured for forming an active therein, and the second silicon layer 56 may comprise a so-called “handle wafer,” which is configured for handling of the substrate 50 by manufacturing and/or processing equipment. Each of the first and second silicon layers 54, 56 may comprise a single crystal of silicon.

Although the first silicon layer 54 and the second silicon layer 56 are shown in FIG. 5A as having substantially equal thicknesses, in actuality, the first silicon layer 54 and the second silicon layer 56 may have thicknesses that differ from one another. By way of example and not limitation, the first silicon layer 54 may have a thickness of less than about one hundred microns (100 μm), the second silicon layer 56 may have a thickness of greater than about one hundred microns (100 μm), and the etch stop layer 52 may have a thickness of between about ten microns (10 μm) and about one hundred microns (100 μm). As one particular, non-limiting example, the first silicon layer 54 may have a thickness of about fifty microns (50 μm), the second silicon layer 56 may have a thickness of about seven-hundred and fifty microns (750 μm), and the etch stop layer 52 may have a thickness of about ten microns (10 μm).

The etch stop layer 52 may comprise a material that is resistant to etching by an etchant that is capable of etching at least the second silicon layer 56. Furthermore, the etch stop layer 52 may be substantially transparent to wavelengths of electromagnetic radiation that are to be detected using the sensor array 12 of the imager device 10 (e.g., visible light), and that has a refractive index close to that of silicon (or any other semiconductive material from which the first layer 54 is formed). This coincidence of refractive indices may prevent refraction of the radiation as it passes through the interface between the etch stop layer 52 and the first silicon layer 54, as discussed in further detail. By way of example and not limitation, the etch stop layer 52 may comprise silicon oxynitride (SiON), silicon dioxide (SiO₂), another oxide material, or a polymer material. Such materials may be configured to be resistant to etchants conventionally used to etch silicon (such as, for example, potassium hydroxide (KOH)), to be transparent to visible light, and to exhibit a refractive index similar to that of silicon, which is typically reported as being between about 3.6 and about 3.8. As known in the art, silicon oxynitride (SiON) can be tailored to exhibit a selected refractive index by adjusting the parameters and conductions under which the SiON is formed. In some embodiments of the present invention, the etch stop layer 52 may comprise a layer of silicon oxynitride (SiON) configured to exhibit a selected refractive index of between about 2.5 and about 4.0.

FIG. 5B is a partial cross-sectional view of a work piece 51 formed by at least partially forming the various active components of each of a plurality of imager devices 10 (FIG. 1) on and/or in the first silicon layer 54 of the substrate 50 using techniques known in the art. It is understood that a plurality of imager devices 10 may be simultaneously fabricated side-by-side on and/or in the first silicon layer 54 of the substrate 50 shown in FIG. 5A. For purposes of illustration, only a portion of the work piece 51 that is to include a single imager device 10 is shown in FIGS. 5B-5F. It is understood, however that the work piece 51 may comprise a plurality of imager devices 10, which may be subsequently singulated from the work piece 51 to provide a plurality of individual and discrete imager devices 10.

As shown in FIG. 5B, a plurality of sensor arrays (12) that each include a plurality of pixels 30 may be formed side-by-side on and/or in the exposed major surface of the first silicon layer 54 of the work piece 51 (i.e., the surface of the first silicon layer 54 opposite the etch stop layer 52). Furthermore, various other components and/or subsystems of the imager device including, for example, row decoders 14, column decoders 16, controllers 18, analog to digital converters 20, pixel processors 22, I/O ports 24 (FIG. 1) may be formed in at least some regions 60 within the first silicon layer 54 laterally beside the sensor arrays 12. As shown in FIG. 5B, the regions 60 that include such other components and/or subsystems may be disposed within the peripheral region 26 of the imager device 10 (FIGS. 3A-3B).

One or more so-called “wiring” or “routing” layers may be formed over the pixels 30. The routing layers each may include one or more of conductive traces 62, conductive vias 64, and conductive pads 66 configured to provide electrical communication between the various components and/or subsystems of each of the imager devices 10 formed in the work piece 51.

The side of the first silicon layer 64 opposite the etch stop layer 52 (i.e., the side of the first silicon layer 64 on and/or in which the various components of the imager devices 10 are formed) is conventionally referred to as the front side 70 of the sensor array 12, while the side of the first silicon layer 64 adjacent the etch stop layer 52 is conventionally referred to as the back side 72 of the sensor array 12.

Referring to FIG. 5C, a resist layer 74 may be selectively provided over regions of the exposed major surface of the second silicon layer 56 opposite the etch stop layer 52 that are laterally beside or adjacent each of the plurality of sensor arrays 12 in and/or on the work piece 51. In other words, the resist layer 74 may be selectively provided over the regions of the second silicon layer 56 that will subsequently define the peripheral regions 26 (FIG. 3A) of each of the imager devices 10 (FIG. 3A) formed on the work piece 51. The resist layer 74 may comprise a conventional photoresist material, which may be blanket deposited over the exposed major surface of the second silicon layer 56 and selectively patterned so as to remove portions of the photoresist material overlying each of the sensor arrays 12 of the work piece 51. Any material that is sufficiently resistant to a particular etchant to be subsequently used to etch away the silicon of the second silicon layer 56 may be used to form the resist layer 74.

Referring to FIG. 5D, after providing the resist layer 74 over selected regions of the second silicon layer 56, the portions of the second silicon layer 56 that are exposed through the resist layer 74 may be etched to remove portions of the second silicon layer 56 overlying the pixels 30 of the sensor array 12 in the first silicon layer 54. For example, a wet chemical etching process or a dry plasma etching process may be used to remove the portions of the second silicon layer 56. As previously discussed, the etch stop layer 52 may be resistant to the etchant used to remove the portions of the second silicon layer 56. The etching process may be continued until the portions of the second silicon layer 56 overlying the pixels 30 of the sensor array 12 are substantially completely removed to expose the etch stop layer 52, as shown in FIG. 5D.

In some embodiments, the etching process may comprise an anisotropic etching process such that after etching, one or more slanted or sloped surfaces 78 extends from the major surface 57 of the second silicon layer 56 toward the sensor array 12 and to the etch stop layer 52, as shown in FIG. 5D. For example, in some embodiments, the crystal structure of the second silicon layer 56 may be oriented such that the exposed major surface 57 of the second silicon layer 56 comprises the (100) silicon plane, and the etching process may be carried out using an anisotropic wet chemical etch using, for example, potassium hydroxide (KOH). The (111) silicon plane may be etched at a relatively slower rate than the (100) silicon plane by potassium hydroxide. As a result, after subjecting the second silicon layer 56 to the anisotropic wet chemical etch, the (111) silicon plane of the second silicon layer 56 may define the sloped surfaces 78 that extend from the major surface 57 of the second silicon layer 56 to the etch stop layer 52, as shown in FIG. 5D. In other words, the sloped surfaces 78 shown in FIG. 5D each may comprise a (111) silicon plane (or a plane equivalent to the (111) silicon plane).

After etching the second silicon layer 56, the remaining portions of the second silicon layer 56 may define structural support members 80 that at least partially surround each of the sensor arrays 12 of the imager devices 10 being formed in the work piece 51. Furthermore, the structurally support members 80 may be disposed in the peripheral regions 26 of the imager devices 10 being formed. The structurally support members 80 may provide structural support to the imager devices 10. For example, the structural support members 80 may serve to prevent flexural bending of the sensor arrays 12 during fabrication, handling, and operation. Furthermore, the conductive elements 28 may be positioned over or vertically aligned with the structural support members 80, which may serve to facilitate attachment of the imager devices 10 to higher level substrates (not shown) without damaging the imager devices 10, as discussed in further detail below. In view of die above, the durability of the imager devices 10 may be enhanced by the structural support members 80.

Referring to FIG. 5E, after etching the second silicon layer 56, the resist layer 74 may, optionally, be removed.

As also shown in FIG. 5E, a plurality of color filter arrays (CFA) 84 may be formed over the exposed surfaces of the etch stop layer 52, each color filter array 84 corresponding to one imager device 10 being formed in the work piece 51. The color filter arrays 84 each may comprise a plurality of individual electromagnetic radiation filters positioned side-by-side over the etch stop layer 52. In some embodiments, each individual filter in the color filter arrays 84 may be positioned over a single pixel 30 so as to filter the radiation impinging on each respective pixel 30. By way of example and not limitation, the color filter arrays 84 may be configured in a so-called “GRGB Bayer pattern” in which one half of the individual filters are configured to allow green light to pass through the filter while preventing other wavelengths of light from passing through the filter (the “green” or “G” filters), one fourth of the individual filters are configured to allow red light to pass through the filter while preventing other wavelengths of light from passing through the filter (the “red” or “R” filters), and one fourth of the individual filters are configured to allow blue light to pass through the filter while preventing other wavelengths of light from passing through the filter (the “blue” or “B” filters). Imager devices that embody teachings of the present invention are not limited to such color filter array patterns, and the color filter array 84 may comprise any pattern of individual filters. The green, red, and blue filters are interspersed amongst each other in a substantially symmetric pattern. In this configuration, the pixels 30 corresponding to the green filters in the color filter array 84 (the “green pixels”) will detect green light, the pixels 30 corresponding to the red filters in the color filter array 84 (the “red pixels”) will detect red light, and the pixels 30 corresponding to the blue filters in the color filter array 84 (the “blue pixels”) will detect the blue light. In this configuration, the signals generated by the combined green, red, and blue pixels 30 may be combined to generate a full color image.

The individual filters of the color filter arrays 84 may comprise, for example, a polymer material that is configured to exhibit the desired optical filtering properties. Such materials are known in the art and commercially available. The color filter arrays 84 may be formed using any of a variety of techniques, many of which are known in the art. For example, a first liquid polymer precursor material may be blanket deposited over the exposed surface of the etch stop layer 52 and selectively patterned to form the green filters of the color filter arrays 84. In some methods, the liquid polymer precursor material may be spun onto the etch stop layer 52 and selectively cured only at the locations at which it is desired to form the solid green filters. The remaining liquid polymer precursor material between the newly formed solid green filters may be removed from the etch stop layer 52. This process then may be repeated to form the red filters of the color filter arrays 84, and yet again to form the blue filters of the color filter arrays 84. In additional methods, each of the layers of liquid polymer precursor material deposited over the etch stop layer 52 may be cured substantially as a whole and subsequently selectively patterned by removing selected portions thereof using, for example, an etching process or a laser ablation process.

Referring to FIG. 5F, a plurality of microlenses 86 may be formed over each of the color filter arrays 84 on the work piece 51. Each microlens 86 may be farmed over and correspond to one of the individual filters of a color filter array 84 and to one pixel 30. The microlenses 86 each may be configured to focus radiation impinging on the exposed outer surface thereof onto a focal plane in which the corresponding pixel 30 is disposed. The microlenses 86 may comprise, for example, a polymer material that is formulated and configured to exhibit the desired optical properties. The microlenses 86 may be formed using any of a variety of techniques known to those of ordinary skill in the art.

As also shown in FIG. 5F, a plurality of conductive elements 28 may be formed on the work piece 51 to provide the embodiment of the imager device 10 shown in FIGS. 3A-3B. In some embodiments, each of the conductive elements 28 may be located on the front side 70 of the imager device 10 and vertically aligned with the structural support member 80 in the peripheral region 26 of the imager device 10.

In some embodiments, the conductive elements 28 may comprise, for example, conductive balls, bumps, columns, or studs that project from the surface of the imager device 10. In such embodiments, electrical communication may be provided between the imager device 10 and conductive elements of a higher level substrate (not shown), such as a circuit board, by aligning the conductive elements 28 with the conductive elements (e.g., conductive pads) of the higher level substrate and electrically coupling the conductive elements 28 directly to the conductive elements of the higher level substrate. For example, the conductive elements 28 may comprise a solder material, and the conductive elements may be structurally and electrically coupled to conductive elements of the higher level substrate using a conventional solder reflow process. In additional embodiments, the conductive elements 28 may comprise conductive pads or lands that are substantially flush or recessed relative to the surface of the imager device 10. In such embodiments, conventional wire-bonding techniques optionally may be used to provide electrical communication between the imager device 10 and conductive elements of a higher level substrate (not shown), such as a circuit board.

By providing the conductive elements 28 in the peripheral region 26 of the imager device 10, the imager device 10 may be relatively less susceptible to damage during subsequent processes in which the imager device 10 is attached to a higher level substrate (not shown) using the conductive elements 28. Explaining further, compression forces may be applied to the peripheral region 26 of the imager device 10 during, for example, a solder reflow process or a wire-boding process. In imager devices according to embodiments of the present invention, such as the imager device 10, these compression forces may be applied to the imager devices 10 without subjecting the imager devices 10 to significant bending or flexural stresses. Furthermore, the compression forces may be applied only to the peripheral regions of the imager devices, which do not include the relatively fragile sensor array 12. Furthermore, the structural support member 80 may protect any other active components and/or subsystems of the imager device 10 that are located in the peripheral region 26 (e.g., within the regions 60) from damage during application of such compression forces.

After each of the imager devices 10 have been substantially formed on the work piece 51, the imager devices 10 may be singulated from the work piece 51, as known in the art.

In some embodiments, an additional wafer or substrate may be temporarily or permanently secured to the work piece 51 adjacent the front side 70 of the first silicon layer 54. For example, a so-called “dummy wafer,” which may comprise a layer of silicon, may be at least temporarily secured to the front side 70 of the first silicon layer 54 after forming each of the sensor arrays 12 therein. Such a dummy wafer may have a thickness relative greater than that of the first silicon layer 54, and may be used to facilitate handling of the work piece 51 while the second silicon layer 56 is processed to form the structural support member 80, as described above. For example, the dummy wafer may have a thickness of about seven-hundred and fifty microns (750 μm). Optionally, the dummy wafer may be removed from the work piece 51 at a subsequent point in the manufacturing process.

In additional embodiments, an additional wafer or substrate comprising a plurality of so-called “redistribution layers” (RDLs) (each corresponding to one imager device 10) may be secured to the work piece 51 adjacent the front side 70 of the first silicon layer 54. Such a redistribution layer may be used to redistribute the location of the conductive elements 28 on the front side 70 of the imager device 10, which may be useful when imager devices 10 are to be used with a number of different higher level substrates (not shown) having conductive elements disposed in varying patterns and/or locations. In such situations, a redistribution layer may be customized or tailored to suit each of the various higher level substrates.

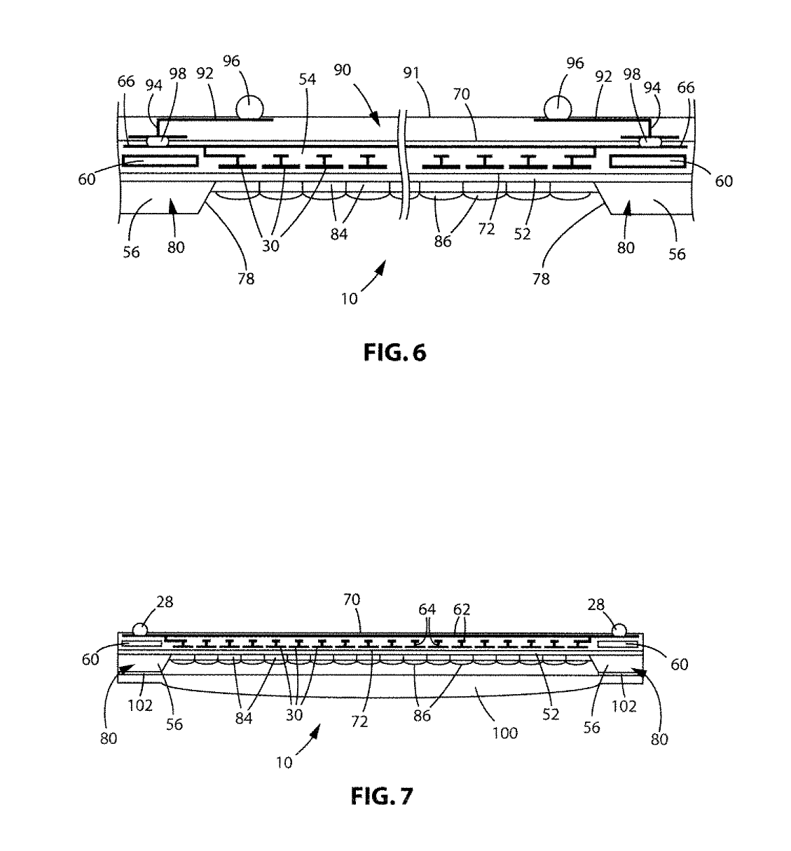

For example, a redistribution layer 90 may be provided on the front side 70 of the imager device 10, as shown in FIG. 6. The redistribution layer 90 may comprise a discrete substrate 91, which may include, for example, a full or partial wafer of silicon. In additional embodiments, the substrate 91 may include a layer of dielectric material such as, for example, a ceramic oxide (e.g., silica) or a polymer material. Conductive traces 92 may extend laterally on or in the substrate 91. In some embodiments, the redistribution layer 90 also may include vertically extending conductive vias 94. The conductive traces 92 and conductive vias 94 of the redistribution layer 90 may be configured and used to provide electrical communication between the conductive pads 66 provided the front side 70 of the first silicon layer 74 of the imager device 10 and conductive elements 96 provided at the exposed major surface 91 of the redistribution layer 90. The conductive elements 96 may comprise, for example, conductive balls, bumps, columns, or studs that project from the surface of the redistribution layer 90, as shown in FIG. 6. In additional embodiments, the conductive elements 96 may comprise conductive pads or lands that are substantially flush or recessed relative to the surface 91 of the redistribution layer 96. Furthermore, electrical communication may be provided between the imager device 10 and conductive elements of a higher level substrate (not shown), such as a circuit board, using the conductive elements 96 as previously discussed in relation to the conductive elements 28 (FIG. 5F).

In some embodiments, electrical communication may be provided between the conductive pads 66 and the conductive traces 92 and conductive vias 94 of the redistribution layer 90 using conductive members 98. In some embodiments, the conductive members 98 may comprise conductive balls, bumps, columns, or studs that structurally and electrically couple the redistribution layer 90 to the other elements of the imager device 10. For example, the conductive members 98 may comprise a solder material, and the redistribution layer 90 may be structurally and electrically coupled to the conductive pads 66 using a conventional solder reflow process. In additional embodiments, the conductive members 98 may comprise a conductive or conductor-filled epoxy material. In yet other embodiments, an anisotropically conductive film (often referred to as a “z-axis” conductive film) may be used to provide electrical communication between the conductive traces 92 and conductive vias 94 of the redistribution layer 90 and the conductive pads 66 provided on or in the first silicon layer 54.

In some embodiments a redistribution layer 90 may be formed separately and attached to an imager device 10 after the imager device 10 is substantially completely formed. In additional embodiments, a plurality of redistribution layers 90 may be attached to a plurality of imager devices 10 at the wafer level. In other words, a plurality of redistribution layers 90 may be fabricated side by side on a relatively larger substrate 91, which may be attached to a work piece 51 comprising a plurality of imager devices 91. For example, a substrate 91 (FIG. 6) comprising a plurality of redistribution layers 90 therein may be attached to a work piece 51 at the stage shown in FIG. 5B (i.e., after processing the first silicon layer 54 to form the pixels 30 and other active components of the imager device 10, but prior to processing the second silicon layer 56 to form the structural support member 80). In additional methods, such a substrate 91 (FIG. 6) may be attached to a work piece 51 after processing both the first and second silicon layers 54, 56.

In additional embodiments, a redistribution layer 90 may be formed directly on and/or in the first silicon layer 54 over the front side 70 of the sensor array 12 of each of the imager devices 10 without using a separate wafer or substrate.

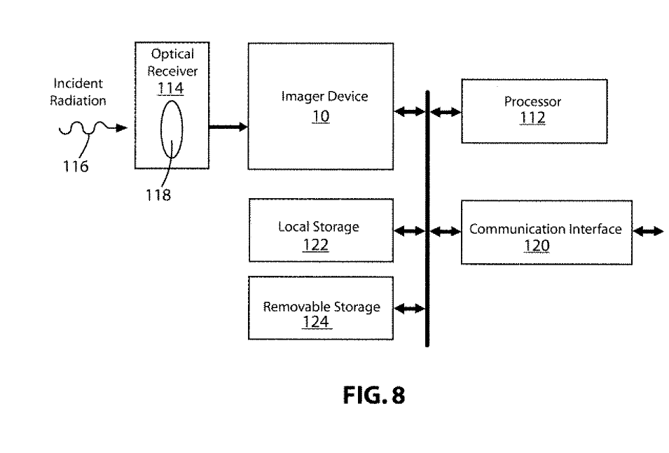

Referring to FIG. 7, in some embodiments, embodiments of imager devices of the present invention, such as the imager device 10, may include a relatively larger lens 100 that is sized, shaped, and otherwise configured to focus and/or collimate radiation (e.g., visible light) onto the sensor array 12. In additional embodiments, the imager device 10 may include a lens stack comprising a plurality of lenses 100 stacked one over another so as to form a stack of lenses that collimates and/or focuses radiation onto the sensor array 12 as necessary or desired. In yet other embodiments, the imager device 10 may include only a relatively larger lens 100 or a stack of relatively larger lenses 100, and may not include any microlenses 86.

By way of example and not limitation, a lens 100 or lens stack may be secured to the structural support member 80 using an adhesive material 102 such as, for example, epoxy or a double-sided adhesive film. As discussed above, a plurality of imager devices 10 may be formed side-by-side on a single substrate 50 (FIG. 5A). Therefore, a plurality of lenses 80 may be formed side-by-side on or in a single lens substrate (not shown), which then may be aligned with and attached to the work piece 51 at the wafer level. For example, the adhesive material may be applied to either the single lens substrate or to the exposed surfaces of the various structural support members 80 formed on the work piece 51, and the lens substrate may be aligned with ad secured to the structural support members 80 of the work piece 51. If the imager device 10 is to include a stack of relatively larger lenses 100, a plurality of lens substrates, each including a plurality of tenses 80 formed side-side thereon, may be provided and stacked one over another to form a unitary structure comprising a plurality of integral stacks of tenses 1 (i.e., lens stacks), which then may be aligned with and secured to the work piece 51 at the wafer level. The individual imager devices 10 may be singulated from the work piece 51 in a subsequent process.

Embodiments of imager devices of the present invention may exhibit increased quantum efficiency (QE) relative to known imager devices, while maintaining sufficient structural strength and durability. The quantum efficiency of an imager device may be defined as the ratio of the number of photons that impinge on an imager device and actually result in the generation of a unit of charge in the imager device to the total number of photons impinging on the imager device. Imager devices known in the art typically exhibit average quantum efficiencies of between about twenty-five percent (25%) and about forty percent (40%). Imager devices that are configured for back side illumination and that embody teachings of the present invention may exhibit an average quantum efficiency greater than imager devices presently known in the art. For example, some imager devices that embody teachings of the present invention may exhibit an average quantum efficiency of greater than about fifty percent (50%). The increased quantum efficiency may be at least partially due to the minimal amount of material the photons must pass through before reaching a photosensitive device of a pixel in the sensor array (such as, for example, the photodiode 32 of the pixel 30 shown in FIGS. 4A-4C). By configuring an imager device for back side illumination, as previously described herein, the amount of material that each photon must pass through before reaching a photosensitive device may be decreased or minimized relative to imager devices known in the art. Furthermore, by utilizing a structural support member in accordance with teachings of the present invention, imager devices may be configured for back side illumination while maintaining sufficient structural strength and durability.

Embodiments of imager devices of the present invention, such as the imager device 10 shown in FIGS. 1, 2, and 3A-3B, may be used to provide embodiments of imaging systems of the present invention.

FIG. 8 is a simplified block diagram illustrating one embodiment of an imaging system 110 according to the present invention. In some embodiments, the imaging system 110 may comprise, for example, a digital camera, a cellular telephone, a computer, a personal digital assistant (PDA), or any other device or system capable of capturing an electronic representation of an image. The imaging system includes an imager device that embodies teachings of the present invention, such as the imager device at previously described herein. The imaging system 110 may include an electronic signal processor 112 for receiving electronic representations of images from the imager device 10 and communicating the images to other components of the imaging system 110. The imaging system 110 may also include an optical receiver 114 for channeling, focusing, or modifying incident radiation 116 (e.g., visible light) and otherwise presenting an image to the imager device 10. For example, the optical receiver 114 may include a lens 118 for focusing the incident radiation 116 onto the imager device 10.

The imaging system 110 also may include a communication interface 120 for transmitting and receiving data and control information. In some embodiments, the imaging system 110 also may include one or more memory devices. By way of example and not limitation, the imaging system may include a local storage device 122 (e.g., a read-only memory (ROM) device and/or a random access memory (RAM) device) and a removable storage device 124 (e.g., flash memory).

Although the foregoing description contains many specifics, these should not be construed as limiting the scope of the present invention but merely as providing illustrations of some exemplary embodiments. Similarly, other embodiments of the invention may be devised which do not depart from the spirit or scope of the present invention. Features from different embodiments may be employed in combination. The scope of the invention is, therefore, indicated and limited only by the appended claims and their legal equivalents, rather tan by the foregoing description. All additions, deletions, and modifications to the invention, as disclosed herein, which fall within the meaning and scope of the claims are to be embraced thereby.

1. An imager device comprising:
a sensor array comprising a plurality of pixels formed in a front side of a first layer of light-transmissive material;
a structural support member at least partially surrounding the sensor array and positioned on a back side of the first layer of material to enable illumination of the sensor array through the back side; and
at least one conductive element on the front side of the first layer of material for communicating electrically with the sensor array.

2. The imager device of claim 1, further comprising an etch stop layer between the first layer of material and the structural support member.

3. The imager device of claim 2, wherein the etch stop layer comprises at least one of an oxide material and a polymer material.

4. (canceled)

5. The imager device of claim 2, wherein the etch stop layer has a refractive index that substantially matches a refractive index of the light-transmissive material.

6. The imager device of claim 1, wherein the at least one conductive element is vertically aligned with the structural support member.

7-8. (canceled)

9. The imager device of claim 1, wherein the structural support member substantially entirely surrounds the sensor array.

10. The imager device of claim 1, wherein the structural support member comprises a sloped surface extending from a major surface of the structural support member toward the sensor array.

11. The imager device of claim 1, wherein the structural support member has a thickness of greater than about one hundred microns (100 μm).

12-14. (canceled)

15. The imager device of claim 1, further comprising a color filter array disposed over the back side of the first layer of material.

16-17. (canceled)

18. The imager device of claim 1, further comprising at least one lens attached to the structural support member and configured to focus radiation onto the sensor array.

19. (canceled)

20. An imager device comprising:
a sensor array comprising a plurality of pixels formed in a front side of a first layer of light-transmissive material;
a structural support member at least partially surrounding the sensor array and positioned on the back side of the first layer of material to enable illumination of the sensor array through the back side; and
a plurality of conductive elements for communicating electrically with the sensor array, each conductive element of the plurality of conductive elements located on the front side of the first layer of material and vertically aligned with the structural support member.

21-27. (canceled)

28. The imager device of claim 20, further comprising at least one lens attached to the structural support member and configured to focus radiation onto the sensor array.

29. An imaging system for capturing an electronic representation of an image, the imaging system comprising:
at least one electronic signal processor;
at least one memory storage device; and
at least one imager device configured to communicate electrically with the at least one electronic signal processor and the at least one memory storage device, the at least one imager device comprising:
a sensor array comprising a plurality of pixels formed in a front side of a first layer of light-transmissive material;
a structural support member at least partially surrounding the sensor array and positioned on the back side of the first layer of material to enable illumination of the sensor array through the back side; and
at least one conductive element on the front side of the first layer of material for communicating electrically with the sensor array.

30. The imaging system of claim 29, wherein the imaging system comprises at least one of a digital camera, a cellular telephone, a computer, and a personal digital assistant (PDA).

31-35. (canceled)

36. A method of forming an imager device, the method comprising:
forming a sensor array comprising a plurality of pixels on a front side of a first layer of light-transmissive material;
providing a structural support member on a back side of the first layer of material in a configuration to at least partially surround the sensor array and enable exposure of the sensor array to illumination through the back side; and
providing at least one conductive element on the front side of the first layer of material for communicating electrically with the sensor array.

37. The method of claim 36, wherein providing the structural support member comprises:
securing a second layer of material to the back side of the first layer of material; and
removing at least a portion of the second layer of material overlying the sensor array.

38. The method of claim 37, further comprising providing an etch stop layer between the first layer of material and the second layer of material.

39. (canceled)

40. The method of claim 38, wherein providing an etch stop layer comprises causing the etch stop layer to have a refractive index substantially matching a refractive index of the light-transmissive material.

41-42. (canceled)

43. The method of claim 36, wherein providing at least one conductive element on the front side of the first layer of material comprises vertically aligning the at least one conductive element with the structural support member.

44. (canceled)

45. The method of claim 36, wherein causing the structural support member to at least partially surround the sensor array comprises causing the structural support member to entirely surround the sensor array.

46. The method of claim 36, further comprising providing a sloped surface on the structural support member extending from a major surface of the structural support member toward the sensor array.

47-50. (canceled)

51. The method of claim 36, further comprising attaching at least one lens to the structural support member and configuring the lens to focus radiation onto the sensor array.

52. The method of claim 36, further comprising providing a redistribution layer over the front side of the first layer of material.

53. (canceled)

54. The method of claim 52, wherein providing a redistribution layer over the front side of the first layer of material comprises providing the redistribution layer over the front side of the first layer of material after providing the structural support member on the back side of the first layer of material.

55. A method of forming a plurality of imager devices, the method comprising:
providing a substrate comprising a first layer of light-transmissive material;
forming a plurality of sensor arrays each comprising a plurality of pixels on a front side of the first layer of material;
providing a plurality of structural support members on the back side of the first layer of material and configuring each structural support member of the plurality of structural support members to at least partially surround one sensor array of the plurality of sensor arrays and enable exposure of the sensor arrays to illumination through the back side; and
providing a plurality of conductive elements on the front side of the first layer of material for communicating electrically with the sensor arrays of the plurality of sensor arrays.

56-65. (canceled)
